(19) United States
(12) Patent Application Publication
(10) Pub. No.: US 2013/0133932 A1
(43) Pub. Date: May 30, 2013

(54) METAL PCB HAVING HOLE REFLECTIVE SURFACE AND METHOD FOR MANUFACTURING THE SAME

(71) Applicant: Jong-Jin JANG, Suwon-si (KR)

(72) Inventor: Jong-Jin JANG, Suwon-si (KR)

(73) Assignees: DOOSUNG ADVANCED TECHNOLOGY CO., LTD., Suwon-si (KR); Jong-Jin Jang, Suwon-si (KR)

(21) Appl. No.: 13/557,106

(22) Filed: Jul. 24, 2012

(30) Foreign Application Priority Data
Nov. 29, 2011 (KR) 10-2011-0126095

(51) Int. Cl. H05K 3/00; H05K 1/03

(52) U.S. Cl. 174/255; 29/829

(57) ABSTRACT

A metal printed circuit board (PCB) having a hole reflective surface and a method for manufacturing the same, in which a process of forming a reflective surface by performing surface treatment on a metal plate and a process of bonding a PCB having a hole are performed as a single process, thus simplifying the manufacturing process and increasing the applicability of a product. The metal PCB includes a metal plate having a first reflective surface formed on a chip bonding area by surface treatment; a PCB layer stacked on the metal plate and having a hole and a wiring pattern which are formed in the chip bonding area; a second reflective surface formed on the inner side of the hole of the PCB layer; and a dam formed around the hole on the PCB layer.

### CROSS-REFERENCE TO RELATED PATENT APPLICATION

This application claims the benefit of Korean Patent Application No. 10-2011-0126095, filed on Nov. 29, 2011, in the Korean Intellectual Property Office, the disclosure of which is incorporated herein in its entirety by reference.

### BACKGROUND OF THE INVENTION

1. Field of the Invention

The present invention relates to a metal printed circuit board (PCB) and, more particularly, to a metal PCB having a hole reflective surface and a method for manufacturing the same, in which a process of forming a reflective surface by performing surface treatment on a metal plate and a process of bonding a PCB having a hole are performed as a single process, thus simplifying the manufacturing process and increasing the applicability of a product.

2. Description of the Related Art

In general, a light emitting diode (LED) is a device that emits light by recombination of electrons and holes at a P-N junction upon application of an electric current and is typically fabricated as an LED package in which an LED chip is mounted.

The LED package is mounted on a printed circuit board (PCB) and receives an electric current from electrodes formed on the PCB to emit light.

In the LED package, heat generated from the LED chip has a direct effect on the light emitting performance and lifespan of the LED package. The reason for this is that dislocation and mismatch occur in a crystalline structure of the LED chip when the heat generated from the LED chip remains in the LED chip for a long time.

Recently, a high power LED package has been developed. The high power LED is operated by high voltage power, and thus a large amount of heat is generated from an LED chip by the high voltage power. Therefore, a separate device for effectively dissipating the generated heat is required.

To solve this problem, an LED package with improved heat dissipation performance using a metal PCB in which an insulating layer and a metal pattern layer are sequentially formed on an aluminum base has been developed in the prior art.

For example, the LED package of the prior art is fabricated in such a manner that a hole cup is formed by partially exposing the aluminum base upward by groove processing such as cutting, etc., an LED chip is attached to the hole cup, and then the LED chip and the metal pattern layer are connected by a conductive wire.

However, the LED package of the prior art does not comprise a lead structure for electrically connecting the LED chip to external electrodes, and thus it is difficult to mount the LED package on a typically used PCB.

This means that the compatibility of the LED package with existing electronic equipment or lighting equipment is significantly reduced.

Moreover, it can be seen from manufacturers involved in the manufacturing of high-efficiency LED products that such LED products are manufactured through a complex multi-stage process involving various manufacturers such as a metal PCB manufacturer, a PCB manufacturer, an LED package manufacturer, a lighting manufacturer, an LED module manufacturer, etc. as shown in the following table 1.

TABLE 1

| | |
|---|---|
| Metal PCB manufacturer | Manufacture of metal PCBs (by stacking metal plate and copper foil) |
| PCB manufacturer | Manufacture of films based on PCB artwork files designed by lighting |
| | manufacturer → |
| | Purchase of metal PCBs from metal PCB manufacturer → |
| | Manufacture of metal PCBs designed by lighting manufacturer through |
| | various PCB manufacturing processes such as photosensitization of |
| | films on metal PCBs → |
| | Inspection and shipment |
| LED package manufacturer | Purchase of bare chips → |
| | Purchase of lead frames and package subsidiary materials → |
| | Manufacture of LED packages |
| Lighting manufacturer | Purchase of metal PCBs from PCB manufacturer → |
| | Purchase of LED packages from LED package manufacturer |
| LED module manufacturer | Receiving metal PCBs and LED packages from lighting manufacturer, |
| | mounting LED packages in predetermined positions of metal PCB using |
| | SMT, and performing reflow process → |
| | Inspection and delivery of completed sub-assemblies to lighting |
| | manufacturer |
| Lighting manufacturer | Manufacture and supply of LED lighting products through various |
| | processes using completed sub-assemblies |

First, when a metal PCB manufacturer manufactures metal PCBs (by stacking a metal plate and a copper foil), a PCB manufacturer receiving the metal PCBs manufactures films based on PCB artwork files designed by a lighting manufacturer.

When the circuit design films are manufactured, the metal PCB manufacturer purchases the metal PCBs from the metal PCB manufacturer, manufactures metal PCBs designed by the lighting manufacturer through various PCB manufacturing processes such as photosensitization of the films on the metal PCBs, performs inspection, and makes shipment.

Then, an LED package manufacturer purchases LED bare chips, lead frames, and package subsidiary materials, and manufactures LED packages.

Then, the lighting manufacturer purchases the metal PCBs from the PCB manufacturer, purchases the LED packages from the LED package manufacturer, manufactures LED lighting products through various processes using completed sub-assemblies supplied from an LED module manufacturer, and supplies the LED lighting products.

Then, the LED module manufacturer receives the metal PCBs and LED packages from the lighting manufacturer, mounts the LED packages in predetermined positions of the metal PCB using surface mount technology (SMT), performs a reflow process, performs inspection, and delivers the completed sub-assemblies to the lighting manufacturer.

This manufacturing process of the LED products according to the prior art is a complex multi-stage process involving various manufacturers, and thus it is difficult to maintain quality control. Moreover, there are many limiting factors in manufacturing the high-efficiency LED products such as formation of reflective surfaces, etc., which is problematic.

In the process of manufacturing the metal PCBs according to the prior art, a method of plating the surface of the metal plate is used to form a first reflective structure, which results in an increase in manufacturing costs.

Moreover, in the case where a reflective surface in the form of a cup is formed to form a second reflective structure, the LED chip is bonded to a position lower than the surface of the metal plate, which increases the complexity of its connection to a circuit pattern, for example.

Furthermore, as shown in FIG. 1, when the metal PCB manufacturer delivers the metal PCBs, each formed by bonding a PCB layer to a metal plate using an adhesive layer by hot press, to the PCB manufacturer, the PCB manufacturer manufactures the PCBs by exposing and etching. In this case, there is a problem of heat dissipation due to the presence of the adhesive layer in the area where the LED chip is located.

According to the prior art, in order to form a dam to prevent a fluorescent material from spreading during application of the fluorescent material, an upper substrate is added, or a dam-forming material is applied using a dispenser. In this case, the manufacturing costs are further increased, and the dam structure is not uniform, thus affecting the color temperature.

### SUMMARY OF THE INVENTION

The present invention has been made in an effort to solve the above-described problems associated with prior art such as the complexity of manufacturing LED products and the difficulty of manufacturing high-efficiency LED products, and an object of the present invention is to provide a metal PCB having a hole reflective surface and a method for manufacturing the same, in which a process of forming a reflective surface by performing surface treatment on a metal plate and a process of bonding a PCB having a hole are performed as a single process, thus simplifying the manufacturing process and increasing the applicability of a product.

Another object of the present invention is to provide a metal PCB having a hole reflective surface and a method for manufacturing the same, in which a process of forming a first reflective structure is achieved by performing surface treatment such as chemical polishing, etc. on a metal plate, instead of a high cost process such as plating, etc. and a process of forming a second reflective structure is achieved by forming a reflective surface on the side of a hole formed in a PCB layer, not on the metal plate, thus reducing the manufacturing costs and simplifying the process.

Still another object of the present invention is to provide a metal PCB having a hole reflective surface and a method for manufacturing the same, in which a process of forming a second reflective structure is achieved by forming a reflective surface on the side of a hole formed in a PCB layer, not on a metal plate, such that an LED chip may be bonded to the surface of the metal plate, thus reducing the process and increasing the reflection efficiency of light.

Yet another object of the present invention is to provide a metal PCB having a hole reflective surface and a method for manufacturing the same, in which a process bonding of a PCB layer to a metal plate is performed after forming a hole in the PCB layer such that an adhesive may not remain on a chip bonding area, thus improving heat dissipation characteristics.

Still yet another object of the present invention is to provide a metal PCB having a hole reflective surface and a method for manufacturing the same, in which a dam to prevent a fluorescent material from spreading during application of the fluorescent material is formed by applying white ink, thus reducing the cost of forming a dam structure and providing a uniform dam structure.

A further object of the present invention is to provide a metal PCB having a hole reflective surface and a method for manufacturing the same, which provides a single process of bonding a metal plate having a first reflective structure formed by surface treatment to a PCB having a hole, thus facilitating quality control and manufacture of high-efficiency LED products.

Another further object of the present invention is to provide a metal PCB having a hole reflective surface and a method for manufacturing the same, which supplies a metal PCB, in which a metal plate having a first reflective structure formed by surface treatment is bonded to a PCB having a hole with a second reflective surface structure, to users, thus allowing the users to manufacture high-efficiency LED products by a simplified process.

The objects of the present invention are not limited to the above-mentioned objects, and other objects that are not mentioned will be clearly understood by those skilled in the art from the following description.

According to an aspect of the present invention to achieve the above object of the present invention, there is provided a metal printed circuit board (PCB) having a hole reflective surface, the metal PCB comprising: a metal plate having a first reflective surface formed on a chip bonding area by surface treatment; a PCB layer stacked on the metal plate and having a hole and a wiring pattern which are formed in the chip bonding area; a second reflective surface formed on the inner side of the hole of the PCB layer; and a dam formed around the hole on the PCB layer.

The metal plate and the PCB layer may be bonded by hot press.

The dam may be formed by repeatedly applying white ink and have a minimum height of 200 μm.

According to another aspect of the present invention to achieve the above object of the present invention, there is provided a method for manufacturing a metal PCB having a hole reflective surface, the method comprising: forming a first reflective surface by increasing the reflectivity of the surface of a metal plate by surface treatment; forming a hole and a wiring pattern by patterning a copper foil used as a PCB layer; forming a second reflective surface on the inner side of the hole by plating; stacking and bonding the PCB layer having the hole and the second reflective surface formed in the inner side of the hole to the metal plate having the first reflective surface; and forming a dam around the hole on the PCB layer.

The surface treatment of the metal plate to form the first reflective surface may be performed by chemical polishing.

The process of forming the second reflective surface may comprise: forming the hole and then forming the wiring pattern after plating the inner side of the formed hole with copper; and plating the inner side of the hole with nickel as a buffer layer for silver plating and then plating the nickel-plated inner side of the hole with silver.

The dam may be formed by repeated applying white ink by spring printing.

The process of bonding the PCB layer to the metal plate may be performed by hot press.

The process of bonding the PCB layer to the metal plate may comprise applying an adhesive to the bottom surface of the PCB layer having the hole and the second reflective surface formed on the inner side of the hole such that the adhesive does not remain on the bottom surface of the hole corresponding to a chip bonding area of the metal plate after bonding.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic diagram showing a process of manufacturing a metal PCB according to a prior art;

FIGS. 2A to 2G are cross-sectional views showing a process of manufacturing a metal. PCB having a hole reflective surface according to the present invention;

FIG. 3 is a schematic diagram showing an LED die bonding process using a metal PCB having a hole reflective surface according to the present invention; and

FIG. 4 is an image of a product using a metal PCB having a hole reflective surface according to the present invention.

### DETAILED DESCRIPTION OF THE INVENTION

Hereinafter, preferred embodiments of a metal PCB having a hole reflective surface and a method for manufacturing the same according to the present invention will be described in detail with reference to the accompanying drawings.

Features and advantages of the metal PCB having a hole reflective surface and the method for manufacturing the same according to the present invention will be apparent from the following detailed description of the preferred embodiment of the present invention.

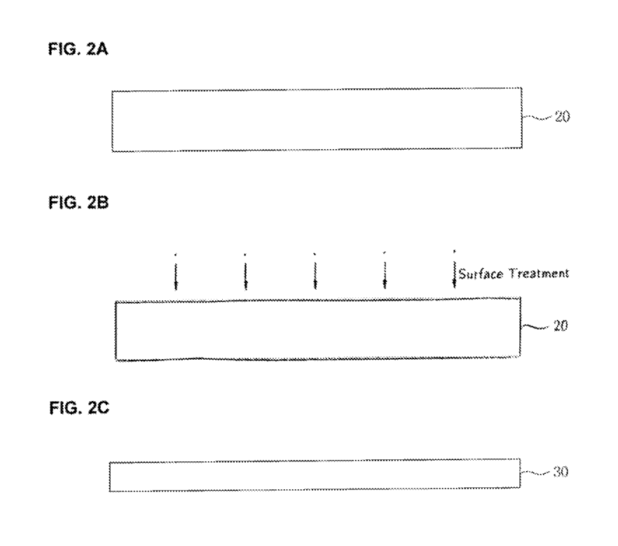

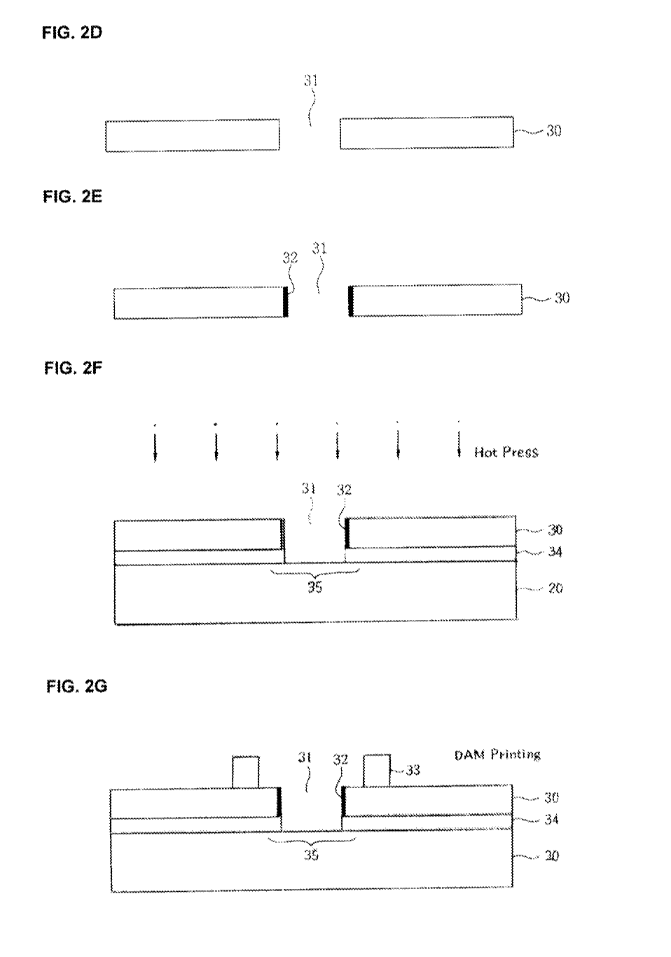

FIGS. 2A to 2G are cross-sectional views showing a process of manufacturing a metal PCB having a hole reflective surface according to the present invention.

The present invention provides a metal PCB having a hole reflective surface and a method for manufacturing the same, in which a process of forming a first reflective structure is achieved by performing surface treatment such as chemical polishing, etc. on a metal plate, instead of a high cost process such as plating, etc. and a process of forming a second reflective structure is achieved by forming a reflective surface on the side of a hole formed in a PCB layer, not on the metal plate, such that a process of bonding the metal plate to the PCB layer is performed as a single process.

A metal PCB having a hole reflective surface according to the present invention comprises a metal plate 20 having a first reflective surface 35 formed in a chip bonding area by surface treatment, a PCB layer 30 stacked on the metal plate 20 and having a hole 31 and a wiring pattern which are formed in the chip bonding area, a second reflective surface 32 formed on the inner side of the hole 31 of the PCB layer 30, a dam 33 formed around the hole 31 on the PCB layer 30, and an adhesive 34 for bonding the PCB layer 30 to the metal plate 20.

Here, the process of bonding the PCB layer 30 to the metal plate 20 is performed by hot press.

The dam 33 is to prevent a fluorescent material from spreading during application of the fluorescent material and is formed by applying white ink. Preferably, the dam 33 has a minimum height of 200 μm.

Screen printing is used to apply the white ink only to a dam-forming area.

A process of manufacturing the above-described metal PCB having the hole reflective surface according to the present invention will now be described.

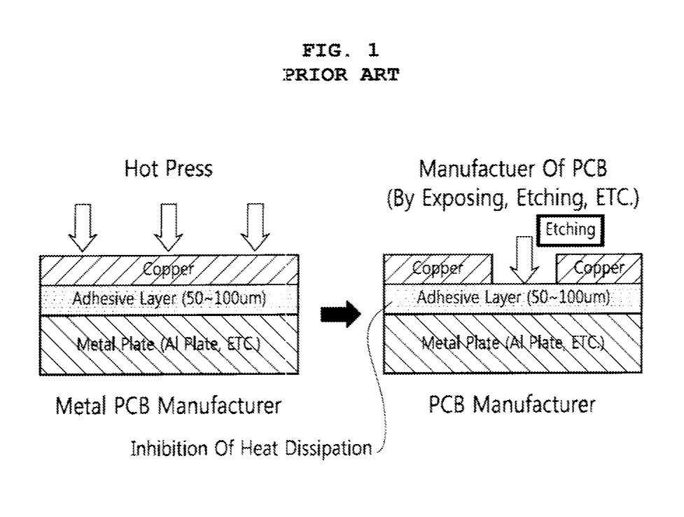

First, as shown in FIG. 1A, a metal plate 20 is prepared, and as shown in FIG. 2B, surface treatment such as chemical polishing, etc. is performed on the surface of the metal plate 20 to form a first reflective surface, thus increasing the reflectivity of the surface of the metal plate 20.

Here, in the process of forming the first reflective surface by performing the surface treatment such as chemical polishing, etc. on the metal plate 20, the surface treatment may be performed on the entire surface of the metal plate 20 or may be selectively performed on a chip mounting area where an LED chip is mounted.

When aluminum is used for the metal plate 20, an anodizing process to prevent oxidation may be performed after the chemical polishing.

Then, as shown in FIG. 2C, a copper foil used as the PCB layer 30 is prepared, and as shown in FIG. 2D, a hole 31 and a wiring pattern are formed by exposing and etching.

Here, the hole 31 is first formed, and the wiring pattern is formed after plating the inner side of the formed hole 31 with copper (Cu).

Subsequently, as shown in FIG. 2E, the inner side of the hole 31 in the PCB layer 30 is plated with nickel as a buffer layer for silver plating and then plated with silver, thus forming a second reflective surface 32.

Moreover, as shown in FIG. 2F, an adhesive 34 is applied to the bottom surface of the PCB layer 30 having the hole 31 and the second reflective surface 32 formed on the inner side of the hole 31, the PCB layer 30 is stacked on the metal plate 20 having the first reflective surface 35, and then the PCB layer 30 and the metal plate 20 are bonded to each other by hot press.

Here, according to the prior art, an etching process is performed to form the wiring pattern after bonding the PCB layer to the metal plate, and thus the adhesive remains on the chip bonding area. However, according to the present invention, after the process of forming the hole 31 and the wiring pattern, the PCB layer 30 and the metal plate 20 are stacked and then bonded by hot press, and thus the adhesive used in the process of bonding the PCB layer 30 to the metal plate 20 does not remain on the chip bonding area.

Lastly, as shown in FIG. 2G, a dam 33 to prevent a fluorescent material from spreading during application of the fluorescent material is formed around the hole 31 on the PCB layer 30.

Here, the dam 33 is formed by applying white ink, and screen printing is used to apply the white ink only to a dam-forming area.

In detail, the dam 33 is formed by repeatedly applying and drying the white ink by spring printing until it has a height of 200 μm or higher.

This process of forming the dam 33 can reduce the cost of forming a dam structure and provide a uniform dam structure, thus ensuring the uniformity of products.

A process of bonding an LED chip to the metal PCB having the hole reflective surface formed by the above-described process will now be described.

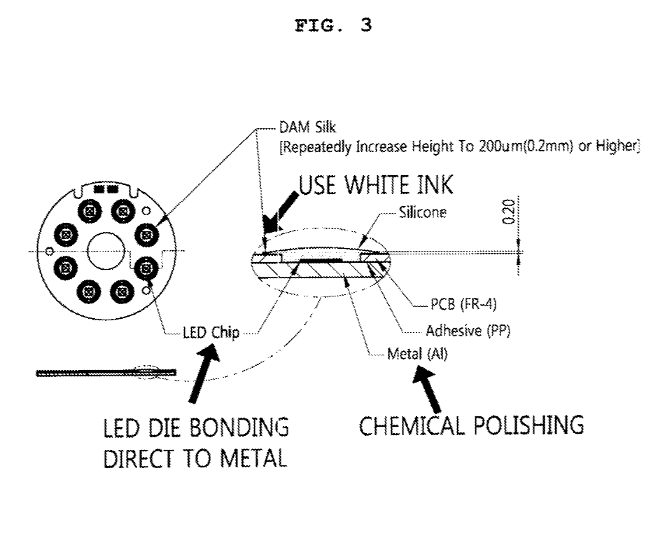

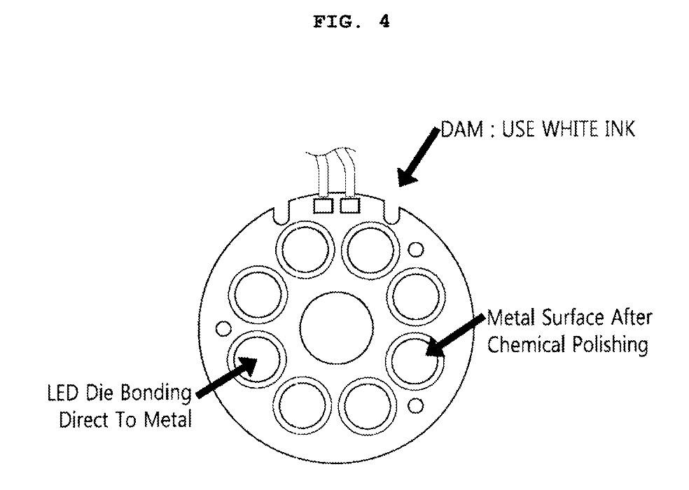

FIG. 3 is a schematic diagram showing an LED die bonding process using a metal PCB having a hole reflective surface according to the present invention, and FIG. 4 is an image of a product using a metal PCB having a hole reflective surface according to the present invention.

As shown in FIG. 3, an LED chip is directly die-bonded to the chip bonding area of the metal PCB having the hole reflective surface according to the present invention, i.e., to the surface of the metal plate 20 having the first reflective surface 35.

The configuration of an LED lighting module formed by the above-described process is shown in FIG. 4.

As such, according to the present invention, the process of forming the first reflective structure is achieved by performing the surface treatment such as chemical polishing, etc. on the metal plate, instead of a high cost process such as plating, etc. the process of forming the second reflective structure is achieved by forming the reflective surface on the side of the hole formed in the PCB layer, not on the metal plate, and the process of bonding the metal plate to the PCB layer is performed as a single process.

With this process, it is possible to simplify the manufacturing process and ensure uniform quality of products.

As described above, the metal PCB having the hole reflective surface and the method for manufacturing the same according to the present invention have the following effects.

First, the process of forming the reflective surface on the metal plate and the process of bonding the PCB are performed as a single process, thus simplifying the manufacturing process.

Second, the process of forming the first reflective structure is achieved by performing surface treatment such as chemical polishing, etc. on the metal plate, instead of a high cost process such as plating, etc., thus reducing the manufacturing costs and simplifying the process.

Third, the process of forming the second reflective structure is achieved by forming the reflective surface on the side of the hole formed in the PCB layer, not on the metal plate, thus reducing the manufacturing costs and simplifying the process.

Fourth, the second reflective structure is formed on the side of the hole formed in the PCB layer such that the LED chip may be bonded to the surface of the metal plate, thus reducing the process and increasing the reflection efficiency of light.

Fifth, the process bonding of the PCB layer to the metal plate is performed after forming the hole in the PCB layer such that an adhesive may not remain on a chip bonding area, thus improving heat dissipation characteristics.

Sixth, the dam to prevent a fluorescent material from spreading during application of the fluorescent material is formed by applying white ink, thus reducing the cost of forming a dam structure and providing a uniform dam structure.

Seventh, it is possible to provide a single process of bonding the metal plate having the first reflective structure formed by surface treatment to the PCB having the hole, thus facilitating quality control and manufacture of high-efficiency LED products.

Eighth, it is possible to supply the metal PCB, in which the metal plate having the first reflective structure formed by surface treatment is bonded to the PCB having the hole with the second reflective surface structure, to users, thus allowing the users to manufacture high-efficiency LED products by a simplified process.

Ninth, it is possible to control the angle of light by controlling the size and thickness of the hole formed in the PCB layer.

While the invention has been shown and described with reference to certain preferred embodiments thereof, it will be understood by those skilled in the art that various changes in form and details may be made therein without departing from the spirit and scope of the invention as defined by the appended claims.

Therefore, the scope of the invention is defined not by the detailed description of the invention but by the appended claims, and all differences within the scope will be construed as being included in the present invention.

What is claimed is:

1. A metal printed circuit board (PCB) having a hole reflective surface, the metal PCB comprising:
a metal plate having a first reflective surface formed on a chip bonding area by surface treatment;
a PCB layer stacked on the metal plate and having a hole and a wiring pattern which are formed in the chip bonding area;
a second reflective surface formed on the inner side of the hole of the PCB layer; and
a dam formed around the hole on the PCB layer.

2. The meal PCB of claim 1, wherein the metal plate and the PCB layer are bonded by hot press.

3. The meal PCB of claim 1, wherein the dam is formed by repeatedly applying white ink and has a minimum height of 200 μm.

4. A method for manufacturing a metal PCB having a hole reflective surface, the method comprising:
forming a first reflective surface by increasing the reflectivity of the surface of a metal plate by surface treatment;
forming a hole and a wiring pattern by patterning a copper foil used as a PCB layer;
forming a second reflective surface on the inner side of the hole by plating;
stacking and bonding the PCB layer having the hole and the second reflective surface formed in the inner side of the hole to the metal plate having the first reflective surface; and
forming a dam around the hole on the PCB layer.

5. The method of claim 4, wherein the surface treatment of the metal plate to form the first reflective surface is performed by chemical polishing.

6. The method of claim 4, wherein the forming of the second reflective surface comprises:
forming the hole and then forming the wiring pattern after plating the inner side of the formed hole with copper; and
plating the inner side of the hole with nickel as a buffer layer for silver plating and then plating the nickel-plated inner side of the hole with silver.

7. The method of claim 4, wherein the dam is formed by repeated applying white ink by screen printing.

8. The method of claim 4, wherein the bonding of the PCB layer to the metal plate is performed by hot press.

9. The method of claim 4, wherein the bonding of the PCB layer to the metal plate comprises applying an adhesive to the bottom surface of the PCB layer having the hole and the second reflective surface formed on the inner side of the hole such that the adhesive does not remain on the bottom surface of the hole corresponding to a chip bonding area of the metal plate after bonding.

10. The method of claim 8, wherein the bonding of the PCB layer to the metal plate comprises applying an adhesive to the bottom surface of the PCB layer having the hole and the second reflective surface formed on the inner side of the hole such that the adhesive does not remain on the bottom surface of the hole corresponding to a chip bonding area of the metal plate after bonding.
